(19) United States
(12) Patent Application Publication
(10) Pub. No.: US 2007/0117226 A1
(43) Pub. Date: May 24, 2007

(54) Method and apparatus for processing timeout in DSG apparatus

(75) Inventor: Gyung-pyo Hong, Yongin-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/519,867

(22) Filed: Sep. 13, 2006

Related U.S. Application Data
(60) Provisional application No. 60/738,041, filed on Nov. 21, 2005.

(30) Foreign Application Priority Data
Dec. 26, 2005 (KR) 10-2005-0129725

(51) Int. Cl. H01L 21/66; H01L 23/58; H01L 21/336

(52) U.S. Cl. 438/14; 438/257; 257/48

(57) ABSTRACT

A method and apparatus for processing a timeout in a device that complies with the DSG standard are provided. The method includes detecting whether a Tdsg4 timeout has occurred in the first device; and transmitting a Tdsg4 timeout message indicating that a Tdsg4 timeout has occurred in the first device to a second device that complies with the DSG standard in response to the detection of a Tdsg4 timeout.

### CROSS-REFERENCE TO RELATED PATENT APPLICATION

This application claims priority from Korean Patent Application No. 10-2005-0129725, filed on Dec. 26, 2005, in the Korean Intellectual Property Office and U.S. Provisional Application No. 60/738,041, filed on Nov. 21, 2005, in the U.S. Patent & Trademark Office, the disclosures of which are incorporated herein in their entirety by reference.

### BACKGROUND OF THE INVENTION

1. Field of the Invention

Apparatuses and methods consistent with the present invention relate to processing a timeout in an apparatus (hereinafter referred to as a DSG apparatus) that complies with the DSG standard.

2. Description of the Related Art

A Data-over-Cable Service Interface Specification Set-top Gateway (DSG) has been adopted in the U.S. as well as in the Republic of Korea as a digital cable broadcast method and has become a standard for digital cable broadcasting throughout the whole of North America. According to the preexisting specification, when DSG data is received in an advanced mode, errors are likely to occur because of a shortage of messages transmitted to an interface protocol between an embedded cable modem (eCM) and an embedded set-top box (eSTB), thus causing the eCM and the eSTB to malfunction.

The DSG standard defines four types of timeouts, including a DSG initialization timeout Tdsg1, a DSG operation timeout Tdsg2, a DSG bilateral retry timer Tdsg3, and a DSG unilateral retry timer Tdsg4.

In a basic mode, the DSG initialization timeout Tdsg1 determines a time out period for DSG packets during the initialization of a DSG eCM, the DSG operation timeout Tdsg2 determines a timeout period for DSG packets while the DSG eCM operates normally, the DSG bilateral retry timer Tdsg3 determines when to retry to reconnect the DSG eCM to a DSG agent and set a bilateral connection between the DSG eCM and the DSG agent, and the DSG unilateral retry timer Tdsg4 determines when to retry to rescan a downstream DOCSIS channel containing DSG packets.

On the other hand, in an advanced mode, the DSG operation timeout Tdsg2 and the DSG unilateral retry timer Tdsg4 are involved in the reception of a downstream channel descriptor (DCD). In the advanced mode, the DSG operation timeout Tdsg2 causes a timeout to occur when no DCD is received even in a normal state, and the DSG unilateral retry timer Tdsg4 is initiated. In other words, an eCM is put in a scan mode if no DCD is received until a timeout occurs in the DSG unilateral retry timer Tdsg4.

FIG. 1 is a flowchart 100 illustrating a DSG operation performed inside an eCM. The flowchart 100 illustrates an operation according to the DSG standard which is excerpted from the Data-over-Cable Service Interface Specifications (DOCSIS) protocol suggested by CableLabs, and the operation illustrated in FIG. 1 is performed by an eCM which transmits several events and DSG data to an eSTB such as a typical digital TV or a typical set-top box (STB).

Referring to the flowchart 100 illustrated in FIG. 1, in operation 101, an eCM is initialized, and a thread (or a process) for performing a DSG operation stands by. In operation 102, a message “Start DSG Advanced Mode” is received from a DSG client controller (DSGCC). In operation 103, a DSG operation stands by.

Thereafter, messages “Receive DSG Tunnel Data”, “Receive DCD Fragment”, “Notification from DSGCC”, “Timeout Tdsg4”, and “Timeout Tdsg2” are received from the DSGCC, and routines corresponding to the respective messages are performed.

In operation 104, in an advanced mode, the message “Receive DCD Fragment” is received from the DSGCC. In operation 105, a DCD is detected. In operation 106, a Tdsg2 timer is reinitiated. In operation 107, a Tdsg4 timer is stopped. In operation 108, DSG information is transmitted to the DSGCC. Then, the method returns to operation 103.

The DSGCC receives a DCD, analyzes the DCD, and determines whether desired DSG data exists in a current channel based on the analysis. If the desired DSG data exists in the current channel, the DSGCC transmits a message “Filter These MAC Addresses & Classifiers” to a DSG operation thread so that predetermined DSG tunnel data can be received, in operation 109. Here, the MAC addresses and the classifiers are parameters handed over to the DSG operation thread by the DSGCC.

In operation 110, the DSG operation thread sends a message indicating that the current channel is a valid DSG channel to other threads. In operation 111, the DSG operation thread transmits DSG tunnel data to the DSGCC while performing an operation to enable tunnel forwarding. In a normal state, DCD data and DSG tunnel data are continuously transmitted to the DSGCC.

In operation 112, if, in the normal state, DCD data transmitted by a DSG agent is not received by the eCM, a timeout may occur in the timer Tdsg2. In operation 113, if a timeout occurs in the timer Tdsg2, the timer Tdsg4 is initiated. In operation 114, a timeout occurs in the timer Tdsg4. Then, in operation 115, the transmission of DSG tunnel data to the DSGCC is terminated. In operation 116, a message “Invalid DSG Channel” is transmitted to a thread (or process) in the eCM other than the DSG operation thread, and then the method returns to operation 103.

The thread which has received the message “Invalid DSG Channel” continues scanning to search for a DSG channel and determines whether a DCD exists in a channel subsequent to the current channel. Therefore, when a timeout occurs in the timer Tdsg4, the eCM does not transmit any message to the DSGCC. Therefore, the DSGCC may not be able to recognize whether the eCM has switched channels to continue scanning.

For example, when a timeout occurs in the timer Tdsg4, the eCM terminates a tunnel forwarding operation and rescans a Data-over-Cable Service Interface Specifications (DOCSIS) downstream. Thereafter, if the eCM receives DCD data from the current channel or receives from a channel other than the current channel DCD data having the same version as the DCD data received from the current channel, the eCM transmits the received DCD data to the DSGCC and waits indefinitely until receiving an operation command from the DSGCC. On the other hand, since the DSGCC does not know whether a timeout has occurred in the timer Tdsg4 in the eCM, the DSGCC still expects that the eCM will have proper setting values and will thus transmit DSG data to the DSGCC normally. Therefore, the eCM waits indefinitely for the DSGCC to issue an operation command without transmitting DSG data to the DSGCC, and the DSGCC waits indefinitely for the eCM to transmit DSG data because it still receives DCD data from the eCM even though the reception of the DCD data has been terminated once.

Therefore, when a timeout occurs in the timer Tdsg4 in the eCM, the eCM and an eSTB including the DSGCC are both likely to be deadlocked while communicating with each other.

### SUMMARY OF THE INVENTION

Consistent with the present invention there are provided a method and apparatus for processing a timeout in a Data-over-Cable Service Interface Specification Set-top Gateway (DSG) apparatus in which, when a timeout occurs in a timer Tdsg4 in an embedded cable modem (eCM), the eCM and an embedded set-top box (eSTB) are prevented from being deadlocked while communicating with each other by transmitting an event message to the eSTB to indicate that a timeout has occurred in the timer Tdsg4.

According to an aspect of the present invention, there is provided a method of processing a timeout in a first device that complies with the Data-over-Cable Service Interface Specification Set-top Gateway (DSG) standard. The method includes detecting whether a Tdsg4 timeout has occurred in the first device; and transmitting a Tdsg4 timeout message indicating that a Tdsg4 timeout has occurred in the first device to a second device that complies with the DSG standard in response to the detection of a Tdsg4 timeout.

The method may also include transmitting new downstream channel descriptor (DCD) information to the second device; and receiving from the second device information that enables the second device to receive desired DSG data.

The first device may include a DSG embedded cable modem, and the second device comprises a DSG client controller or an embedded set-top box comprising a DSG client controller.

The first device may include a host that complies with the OpenCable CableCard Interface specification, and the second device may include a cable card that complies with the OpenCable CableCard Interface specification.

The first device may include a first device in a Downloadable Conditional Access Specification (CAS) system, and the second device may include a second device in the Downloadable CAS system.

According to another aspect of the present invention, there is provided a method of processing a timeout in a second device that complies with the DSG standard. The method includes receiving a Tdsg4 timeout message indicating that a Tdsg4 timeout has occurred from a first device that complies with the DSG standard; and resetting pre-existing DCD information in response to the Tdsg4 timeout message.

The method may also include receiving new DCD information from the first device; and analyzing the new DCD information and transmitting information that enables the second device to receive desired DSG data to the first device.

According to another aspect of the present invention, there is provided an apparatus for processing a timeout in a first device that complies with the DSG standard. The apparatus includes a Tdsg4 timeout detection unit which detects whether a Tdsg4 timeout has occurred in the first device; and a message transmission/reception unit which transmits a Tdsg4 timeout message indicating that a Tdsg4 timeout has occurred in the first device to a second device that complies with the DSG standard in response to the detection of a Tdsg4 timeout.

### BRIEF DESCRIPTION OF THE DRAWINGS

The above and other features and advantages of the present invention will become more apparent by describing in detail exemplary embodiments thereof with reference to the attached drawings in which:

FIG. 1 is a flowchart illustrating a conventional Data-over-Cable Service Interface Specification Set-top Gateway (DSG) operation performed inside an embedded cable modem (eCM);

FIG. 2 is a block diagram of a DSG system according to an exemplary embodiment of the present invention;

FIG. 3 is a flowchart illustrating a method of processing a Tdsg4 timeout according to an exemplary embodiment of the present invention;

FIG. 4 is a flowchart illustrating a DSG operation performed inside an eCM according to an exemplary embodiment of the present invention

FIG. 5 is a flowchart illustrating a method of transmitting messages among an eCM, an embedded set-top box (eSTB), and a DSG client controller (DSGCC) according to an exemplary embodiment of the present invention;

FIG. 6 is a block diagram of an apparatus for processing a Tdsg4 timeout in an eCM according to an exemplary embodiment of the present invention; and

FIG. 7 is a block diagram of an apparatus for processing a Tdsg4 timeout in a DSGCC according to an exemplary embodiment of the present invention.

### DETAILED DESCRIPTION OF THE INVENTION

The present invention will now be described more fully with reference to the accompanying drawings in which exemplary embodiments of the invention are shown.

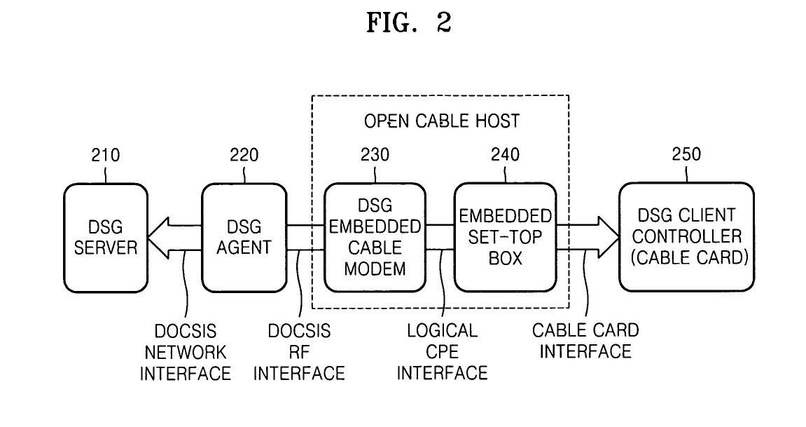

FIG. 2 is a block diagram of a Data-over-Cable Service Interface Specification Set-top Gateway (DSG) system according to an exemplary embodiment of the present invention. Referring to FIG. 2, the DSG system includes a DSG server 210, a DSG agent 220, a DSG embedded cable modem (eCM) 230, an embedded set-top box (eSTB) 240, and a DSG client controller (DSGCC) 250.

The DSG eCM 230 and the eSTB 240 constitute an open cable host. The DSGCC 250 is illustrated in FIG. 2 as being located outside the eSTB 240. However, the DSGCC 250 may be installed inside the eSTB 240.

The DSG server 210 generates a data stream according to an industrial standard and transmits the data stream to the DSG agent 220. For example, the data stream may be identified by a predetermined UDP port number and a predetermined destination IP address.

The DSG agent 220 performs a network interface operation by decapsulating an IP tunneling protocol used between the DSG server 210 and the DSG agent 220 and filtering packets based on a UDP port number and an IP protocol type. Also, the DSG agent 220 performs an RF interface operation by supporting the forwarding of the filtered packets to at least one Data-over-Cable Service Interface Specifications (DOCSIS) downstream channel.

DSG data is received from the DSG server 210 via the DSG agent 220. The DSG server 210 and the DSG agent 220 are collectively referred to as a DSG head end.

A DSG operation performed by the DSG eCM 330 includes searching for a DOCSIS downstream channel having a valid DSG tunnel identifier, obtaining DCD data, securing a DSG tunnel, and forwarding DSG data. The DSG operation may be conducted in one of 2 modes, including a DSG basic mode and a DSG advanced mode.

In the DSG basic mode, the DSG eCM 230 searches for a first DOCSIS channel that includes a well-known Ethernet MAC address to obtain an appropriate DOCSIS downstream channel.

In the DSG advanced mode, the DSG eCM 230 searches for a first DOCSIS channel that contains a DCD message to obtain an appropriate DOCSIS downstream channel, and then transmits the content of the DCG message to the DSGCC 250. The DSGCC 250 determines whether the content of the DCD message is appropriate. In the DSG advanced mode, a DOCSIS MAC management message called a DCD is used. This type of DCD enables DSG tunnels to be dynamically provided.

The DSGCC 250 which can be located inside or outside the eSTB 240 complies with the OpenCable CableCard Interface specification, determines which of DSG data multicast by the DSG head end is to be filtered out and received, and performs all control operations needed for receiving desired DSG data. DSG tunnel packets set by the DSGCC 250 must be forwarded by the DSG eCM 230.

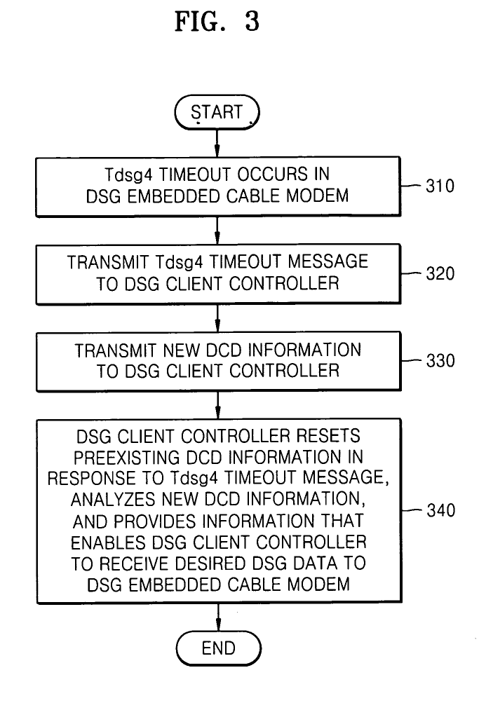

FIG. 3 is a flowchart illustrating a method of processing a Tdsg4 timeout in the DSG system illustrated in FIG. 2 according to an exemplary embodiment of the present invention. Referring to FIG. 3, in operation 310, a Tdsg4 timeout occurs in the DSG eCM 230. In operation 320, the DSG eCM 230 generates a Tdsg4 timeout message indicating that a Tdsg4 timeout has occurred to the DSGCC 250 via the eSTB 240.

In operation 330, the DSG eCM 230 scans DCD data and transmits new DCD information to the DSGCC 250.

In operation 340, the DSGCC 250 receives the Tdsg4 timeout message, recognizes that a Tdsg4 timeout has occurred in the DSG eCM 230, resets pre-existing DCD information, receives the new DCD information, analyses the new DCD information, and transmits information needed for receiving desired DSG data to the DSG eCM 230.

As described above, when a Tdsg4 timeout occurs in the DSG eCM 230, the DSG eCM 230 dynamically notifies the DSGCC 250 that a Tdsg4 timeout has occurred. Accordingly, the DSGCC 250 can recognize that a Tdsg4 timeout has occurred in the DSG eCM 230, reset DCD information, and provide information needed for receiving new DSG data to the DSG eCM 230. Therefore, it is possible to prevent the DSG eCM 230 and the DSGCC 250 from being deadlocked while communicating with each other.

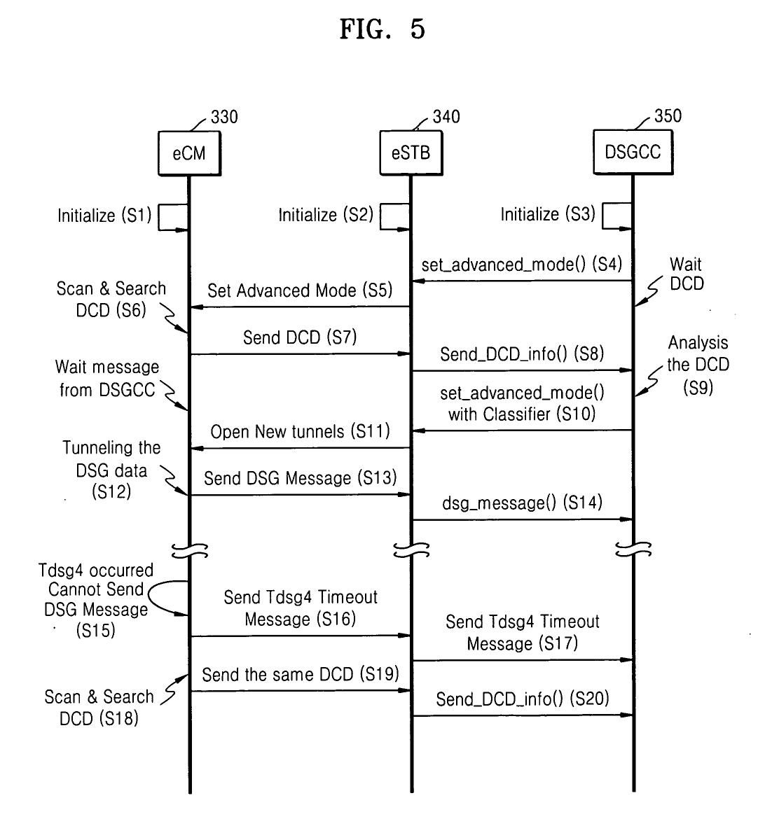

FIG. 5 is a flowchart illustrating a method of transmitting messages among an eCM 330, an eSTB 340, and a DSGCC 350 according to an exemplary embodiment of the present invention. Referring to FIG. 5, the eCM 330, the eSTB 340, and the DSGCC 350 are initialized in operations S1, S2, and S3, respectively.

In operation S4, the DSGCC 350 transmits a message ‘Set Advanced mode’ to the eSTB 340, thereby initiating a DSG advanced mode. In operation S5, the eSTB 340 transmits the message ‘Set Advanced Mode’ to the eCM 330.

In operation S6, the eCM 330 receives the message ‘Set Advanced Mode, begins to operate in the DSG advanced mode, and initiates channel scanning and search operations for finding a DCD. The channel scanning operation is an operation of switching carrier frequencies in units of 6 MHz RF frequencies.

A DCD is a MAC message. Thus, in operation S7, when a DCD exists in a current DOCSIS downstream channel, the eCM 330 stops performing the channel scanning operation and transmits the DCD to the eSTB 340. In operation S8, the eSTB 340 receives the DCD and transmits the DCD to the DSGCC 350.

In operation S9, the DSGCC 350 receives the DCD, analyses the DCD, and determines whether DSG tunnel data desired by the DSGCC 350 exists in the current DOCSIS downstream channel based on the analysis. In operation S10, if the desired DSG tunnel data exists in the current DOCSIS downstream channel, the DSGCC 350 transmits a parameter ‘set_advanced_mode( ) with Classifier’ required for filtering the desired tunnel data to the eCM 330 via the eSTB 340. Then, in operation S11, the DSGCC 350 issues a command to open new tunnels to the eCM 330.

In operation S12, the eCM 330 receives the parameter ‘set_advanced_mode( ) with Classifier’ and filters DSG tunnel data. In operation S13, the eCM 330 transmits a DSG message to the eSTB 340. In operation S14, the eSTB 340 transmits the DSG message to the DSGCC 350.

In a normal state, the eCM 330 continuously transmits a DCD and DSG data to the DSGCC 350.

A DCD includes version information and, when the version information changes, the content of the DCD also changes, which may result in changes in the address and content of DSG tunnel data. Therefore, when version information of a DCD changes, the DSGCC 350 may reanalyze the DCD and reissue a request for DSG tunnel data with a parameter obtained as the analysis result.

If a Tdsg4 timeout occurs due to an error in a cable network in operation S15, the eCM 330 is readily put in a rescan mode in operation S18, and this rescanning ranges from a DOCSIS downstream channel next to the current DOCSIS downstream channel to the current DOCSIS downstream channel.

Thereafter, in operation S16, the eCM 330 transmits a Tdsg4 timeout message indicating that a Tdsg4 timeout has occurred to the eSTB 340. In operation S17, the eSTB 340 receives the Tdsg4 timeout message and transmits the Tdsg4 timeout message to the DSGCC 350 to notify the DSGCC 350 that a Tdsg4 timeout has occurred. Then, the DSGCC 350 recognizes that a Tdsg4 timeout has occurred from the Tdsg4 timeout message, resets pre-existing DCD information, receives new DCD information, and prepares itself to analyze the new DCD information.

In operation S19, if a DCD is determined to exist in the current DOCSIS downstream channel or in a DOCSIS downstream channel other than the current DOCSIS downstream channel while the eCM 330 performs a channel scan operation, the eCM transmits the DCD to the eSTB 340. In operation S20, the eSTB 340 transmits information regarding the DCD to the DSGCC 350. Even if the DCD information transmitted by the eSTB 340 in operation S20 has the same version as DCD information transmitted by the eSTB 340 for a previous DOCSIS downstream channel, the DSGCC 350 determines the DCD information transmitted by the eSTB 340 in operation S20 as being new DCD information because it has already reset the pre-existing DSG information. Thereafter, the DSGCC 350 analyzes the DCD information transmitted by the eSTB 340 in operation S20, and transmits information that enables the DSGCC 350 to receive new DSG tunnel data to the eCM 330 via the eSTB 340.

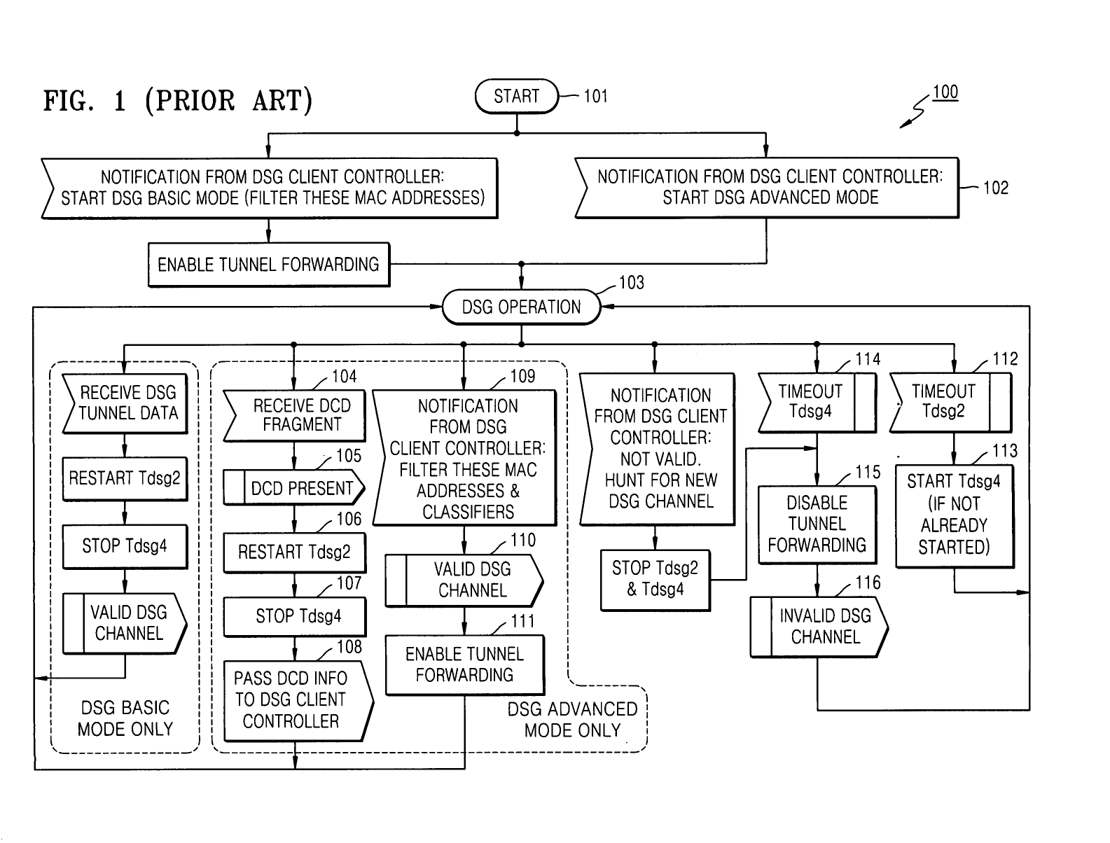

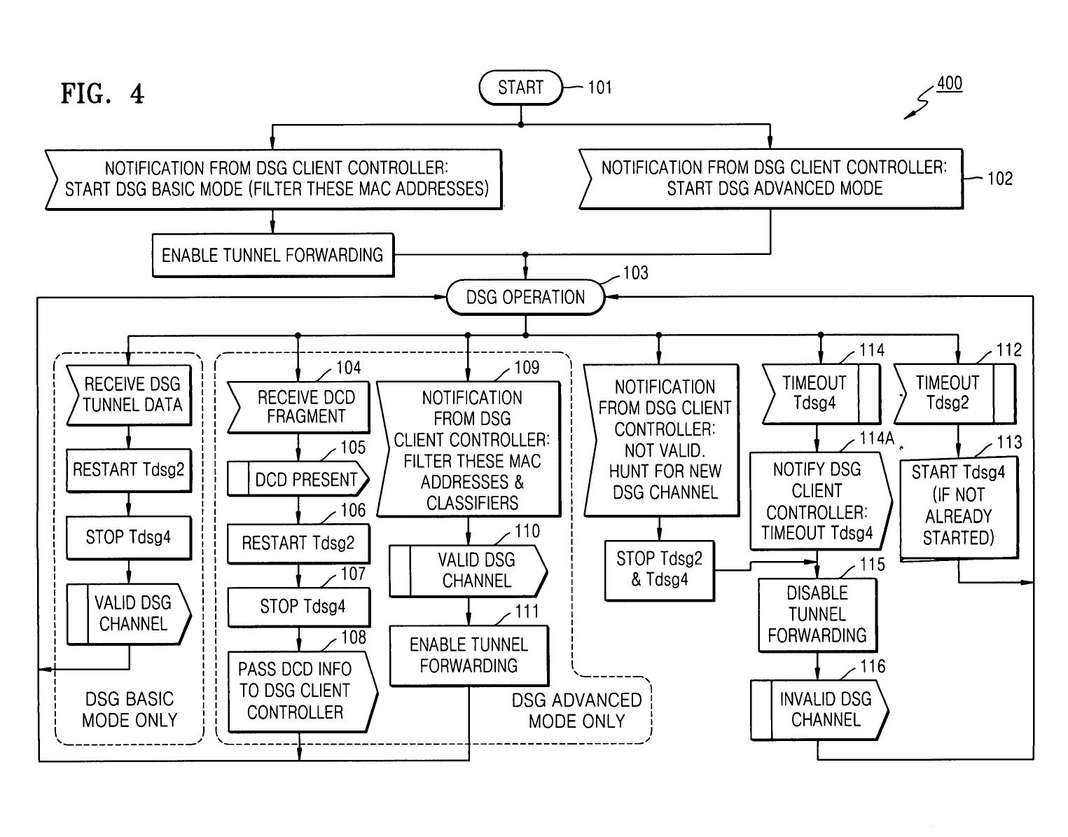

FIG. 4 is a flowchart 400 illustrating a DSG operation performed inside an eCM according to an exemplary embodiment of the present invention. Referring to FIG. 4, the flowchart 400 is similar to the flowchart 100 illustrated in FIG. 1. In FIGS. 1 and 4, like reference numerals represent like functions or operations.

The DSG operation illustrated in the flowchart 400 is slightly different from the DSG operation illustrated in the flowchart 100 in terms of how to process a Tdsg4 timeout. Referring to FIG. 4, when a Tdsg4 timeout occurs in operation 114, an eCM transmits a Tdsg4 timeout message indicating that a Tdsg4 timeout has occurred to a DSGCC in operation 114A. Accordingly, the eCM notifies the DSGCC that a Tdsg4 timeout has occurred by transmitting an event message to the DSGCC, and thus, the DSGCC resets pre-existing DCD information, analyzes new DCD information, and transmits the eCM information that enables the DSGCC to receive new DSG tunnel data.

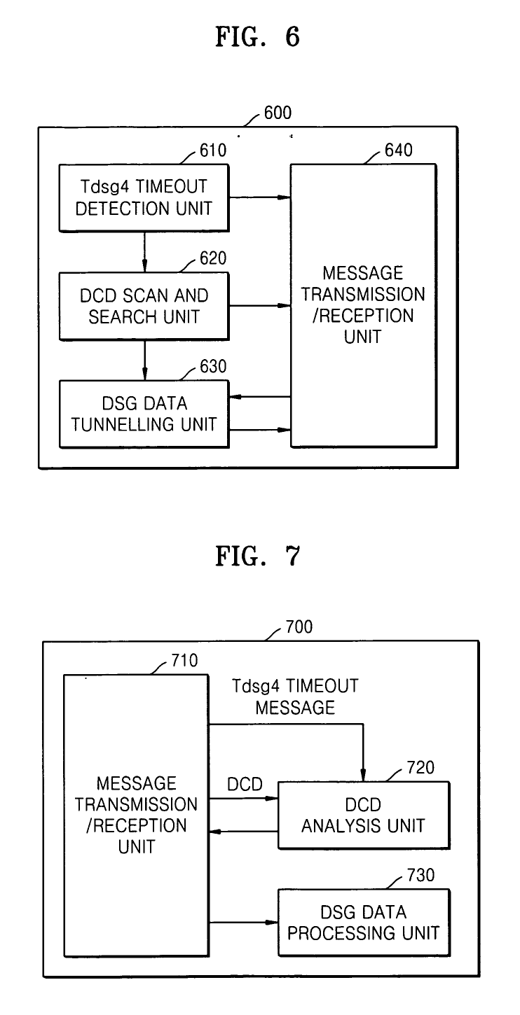

FIG. 6 is a block diagram of an apparatus 600 for processing a Tdsg4 timeout in an eCM according to an exemplary embodiment of the present invention. Referring to FIG. 6, the apparatus 600 includes a Tdsg4 timeout detection unit 610, a DCD scan and search unit 620, a DSG data tunneling unit 630, and a message transmission/reception unit 640.

The Tdsg4 timeout detection unit 610 detects whether a Tdsg4 timeout has occurred in an eCM and transmits a control signal to the message transmission/reception unit 640.

The message transmission/reception unit 640 receives the control signal transmitted by the Tdsg4 timeout detection unit 610, generates a Tdsg4 timeout message indicating that a Tdsg4 timeout has occurred, and transmits the Tdsg4 timeout message to a DSGCC.

If the Tdsg4 timeout detection unit 610 detects a Tdsg4 timeout, it also transmits a control signal to the DCD scan and search unit 620 such that the DCD scan and search unit 620 can initiate an operation of scanning a new DCD.

If a new DCD is found as a result of the scanning operation, the DCD scan and search unit 620 transmits the discovered DCD to the message transmission/reception unit 640, and the message transmission/reception unit 640 transmits the found DCD to the DSGCC.

When the message transmission/reception unit 640 receives information required for tunneling new DSG data from the DSGCC in response to the transmission of the found DCD, it transmits the information to the DSG data tunneling unit 630. Then, the DSG data tunneling unit 630 tunnels DSG data based on the information transmitted by the message transmission/reception unit 640, and transmits the tunneled DSG data to the message transmission/reception unit 640. The message transmission/reception unit 640 transmits the tunneled DSG data to the DSGCC.

FIG. 7 is a block diagram of an apparatus 700 for processing a Tdsg4 timeout in a DSGCC according to an exemplary embodiment of the present invention. Referring to FIG. 7, the apparatus 700 includes a message transmission/reception unit 710, a DCD analysis unit 720, and a DSG data processing unit 730.

When a Tdsg4 timeout message is received from an eCM, the message transmission/reception unit 710 transmits the Tdsg4 timeout message to the DCD analysis unit 720.

The DCD analysis unit 720 receives the Tdsg4 timeout message transmitted by the message transmission/reception unit 710, recognizes that a Tdsg4 timeout has occurred in the eCM, and resets pre-existing DCD information.

When DCD information is received from the eCM, the message transmission/reception unit 710 transmits the DCD information to the DCD analysis unit 720. Since the DCD analysis unit 720 has already reset the pre-existing DCD information, it analyses the DCD information transmitted by the message transmission/reception unit 710 even though the DCD information has the same version as the pre-existing DCD information. The DCD analysis unit 720 provides the message transmission/reception unit 710 with predetermined information that enables a DSGCC to receive desired DCD data as the analysis result.

The message transmission/reception unit 710 receives the desired DSG data from the eCM in return for the predetermined information and transmits the received DSG data to the DSG data processing unit 730. Then, the DSG data processing unit 730 processes the DSG data transmitted by the message transmission/reception unit 710.

The present invention can be applied not only to the DSG standard which is widely used in digital cable broadcasting but also to communication between a host and a cable card which comply with the OpenCable CableCard Interface specification which describes existing DSGCCs. Also, the present invention can be applied to Downloadable Conditional Access Specification (CAS) and can be used for applying a DSG communication protocol to existing legacy set-top boxes.

The method of processing a Tdsg4 timeout according to the present invention can be realized as computer-readable code written on a computer-readable recording medium. The computer-readable recording medium may be any type of recording device in which data is stored in a computer-readable manner. Examples of the computer-readable recording medium include a ROM, a RAM, a CD-ROM, a magnetic tape, a floppy disc, an optical data storage, and a carrier wave (e.g., data transmission through the Internet). The computer-readable recording medium can be distributed over a plurality of computer systems connected to a network so that computer-readable code is written thereto and executed therefrom in a decentralized manner. Functional programs, code, and code segments needed for realizing the method of processing a Tdsg4 timeout according to the present invention can be easily construed by one of ordinary skill in the art.

As described above, according to the present invention, when a Tdsg4 timeout occurs in an eCM, an event message indicating that a Tdsg4 timeout has occurred in the eCM is transmitted to a DSGCC or an eSTB including a DSGCC. Therefore, it is possible to stabilize communication between the eCM and the DSGCC.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of processing a timeout in a first device that complies with the Data-over-Cable Service Interface Specification Set-top Gateway (DSG) standard, comprising:
detecting whether a Tdsg4 timeout has occurred in the first device; and
transmitting a Tdsg4 timeout message indicating that a Tdsg4 timeout has occurred in the first device to a second device that complies with the DSG standard in response to the detection of a Tdsg4 timeout.

2. The method of claim 1 further comprising:
transmitting new downstream channel descriptor (DCD) information to the second device; and
receiving from the second device information that enables the second device to receive desired DSG data.

3. The method of claim 1, wherein the first device comprises a DSG embedded cable modem, and the second device comprises a DSG client controller or an embedded set-top box comprising a DSG client controller.

4. The method of claim 1, wherein the first device comprises a host that complies with the OpenCable CableCard Interface specification, and the second device comprises a cable card that complies with the OpenCable CableCard Interface specification.

5. The method of claim 1, wherein the first device comprises a device in a Downloadable Conditional Access Specification (CAS) system, and the second device comprises another device in the Downloadable CAS system.

6. A method of processing a timeout in a second device that complies with the DSG standard, comprising:
receiving a Tdsg4 timeout message indicating that a Tdsg4 timeout has occurred from a first device that complies with the DSG standard; and
resetting pre-existing DCD information in response to the Tdsg4 timeout message.

7. The method of claim 6 further comprising:
receiving new DCD information from the first device; and
analyzing the new DCD information and transmitting information that enables the second device to receive desired DSG data to the first device.

8. The method of claim 6, wherein the first device comprises a DSG embedded cable modem (eCM), and the second device comprises a DSG client controller or an embedded set-top box (eSTB) comprising a DSG client controller.

9. The method of claim 6, wherein the first device comprises a host that complies with the OpenCable CableCard Interface specification, and the second device comprises a cable card that complies with the OpenCable CableCard Interface specification.

10. The method of claim 6, wherein the first device comprises a first device in a Downloadable Conditional Access Specification (CAS) system, and the second device comprises a second device in the Downloadable CAS system.

11. An apparatus for processing a timeout in a first device that complies with the DSG standard comprising:
a Tdsg4 timeout detection unit which detects whether a Tdsg4 timeout has occurred in the first device; and
a message transmission/reception unit which transmits a Tdsg4 timeout message indicating that a Tdsg4 timeout has occurred in the first device to a second device that complies with the DSG standard in response to the detection of a Tdsg4 timeout.

12. The apparatus of claim 11, wherein the message transmission/reception unit transmits new DCD information to the second device, and receives from the second device information that enables the second device to receive desired DSG data.

13. The apparatus of claim 11, wherein the first device comprises a DSG embedded cable modem (eCM), and the second device comprises a DSG client controller or an embedded set-top box (eSTB) comprising a DSG client controller.

14. The apparatus of claim 11, wherein the first device comprises a host that complies with the OpenCable CableCard Interface specification, and the second device comprises a cable card that complies with the OpenCable CableCard Interface specification.

15. The apparatus of claim 11, wherein the first device comprises a device in a Downloadable Conditional Access Specification (CAS) system, and the second device comprises another device in the Downloadable CAS system.

16. An apparatus for processing a timeout in a second device that complies with the DSG standard, comprising:
a message transmission/reception unit which receives a Tdsg4 timeout message indicating that a Tdsg4 timeout has occurred from a first device that complies with the DSG standard; and
a DCD analysis unit which resets pre-existing DCD information in response to the Tdsg4 timeout message.

17. The apparatus of claim 16, wherein the message transmission/reception unit receives new DCD information from the first device, analyzes the new DCD information, and transmits information that enables the second device to receive desired DSG data to the first device.

18. The apparatus of claim 16, wherein the first device comprises a DSG embedded cable modem (eCM), and the second device comprises a DSG client controller or an embedded set-top box (eSTB) comprising a DSG client controller.

19. The apparatus of claim 16, wherein the first device comprises a host that complies with the OpenCable CableCard Interface specification, and the second device comprises a cable card that complies with the OpenCable CableCard Interface specification.

20. The apparatus of claim 16, wherein the first device comprises a device in a Downloadable Conditional Access Specification (CAS) system, and the second device comprises another device in the Downloadable CAS system.
